(19) United States
(12) Patent Application Publication
(10) Pub. No.: US 2026/0367202 A1
(43) Pub. Date: Nov. 19, 2026

(54) SYSTEMS AND METHODS FOR PERFORMING X-NUCLEAR MAGNETIC RESONANCE SPECTROSCOPY OR MAGNETIC RESONANCE IMAGING ON DIVERSE SYSTEM CONFIGURATIONS

(71) Applicant: The General Hospital Corporation, Boston, MA (US)

(72) Inventors: Jerome L. Ackerman, Charlestown, MA (US); Yi-Fen Yen, Charlestown, MA (US)

(21) Appl. No.: 19/138,698

(22) PCT Filed: Dec. 15, 2023
(86) PCT No.: PCT/US2023/084283

§ 371 Date: Jun. 13, 2025

Related U.S. Application Data
(60) Provisional application No. 63/387,676, filed on Dec. 15, 2022.

(51) Int. Cl. G01R 33/36; G01R 33/46; G01R 33/465; G01R 33/485; G01R 33/56

(52) U.S. Cl. CPC G01R 33/3635; G01R 33/4616; G01R 33/465; G01R 33/485; G01R 33/5608

(57) ABSTRACT

The present disclosure presents methods and system of providing multinuclear imaging and spectroscopy capability' to proton-only magnetic resonance (MR) systems. The system described herein is portable and configured to connect to existing hardware in commercial MR systems. The method and system include a (radio) frequency conversion system that converts the MR system's operating frequency to a frequency corresponding to the Larmor frequencies of target isotopes using the MR system's hardware. The method and system described herein enable X-nuclear MR spectroscopy (MRS) and MR imaging (MRI) on standard clinical MRI scanners without multinuclear capability, thereby providing an economical alternative to the multinuclear system (MNS) provided by the scanner vendors.

### CROSS REFERENCE TO RELATED APPLICATIONS

The present application is based on, claims priority to, and incorporates herein by reference in its entirety for all purposes, U.S. Provisional Application Ser. No. 63/387,676, filed Dec. 15, 2022.

### STATEMENT OF GOVERNMENT SUPPORT

This invention was made with government support under S10OD021569, S10OD021768, R21GM137227, R01AR075077 and R01EB029818 awarded by the National Institutes of Health. The government has certain rights in the invention.

### BACKGROUND

Systems for imaging and spectroscopy are prominent tools used in scientific research, medical care and other technical, industrial and engineering applications. Magnetic resonance (MR) is a fundamental basis for one category of both spectroscopic and imaging systems. Though different in engineering design, both magnetic resonance spectroscopy (MRS) scanners and magnetic resonance imaging (MRI) scanners are carefully designed systems that include highly-engineered hardware configured for precision and accuracy for a given purpose. Often, these systems combine the functions of MRI and MRS. For example, the hardware (electronics, pulse sequencer, data acquisition systems, preamplifiers, RF coils, user interfaces, reconstruction systems, and even analysis and archiving software) of the major vendors of clinical MRI/MRS scanners (that is, those intended to scan humans) are complex, highly-engineered and finely honed systems that have benefited from and shaped by decades of development, the requirements of human safety, and exposure to market forces. In contrast, preclinical MRI/MRS systems (that is, not intended to scan humans) are intended for biomedical and general scientific and technical research. They are designed for the high flexibility that research requires, but tend to offer strikingly lower levels of performance and sophistication in many aspects, for example, the practical number of receiver channels supported, the sophistication of the user interface, workflow efficiency, integrated image reconstruction, analysis and archiving capability, and the ability to perform interventional procedures (which may require real-time pulse sequence modification, integrated device tracking, motion compensation, and image processing and analysis).

The overwhelming majority of clinical scans, and many preclinical scans, employ the MR signals from protons (that is, the nuclei of hydrogen atoms, which are the most abundant atoms in biological tissues and in many chemical compounds) to form images or spectra. Among the advantages of using proton signals in MRI and MRS scanning is the high natural abundance (concentration) of protons, which generally results in the strongest signals and highest quality images and spectra. However, there are many important applications of MRI and MRS in which it is of interest to measure other isotopes, for example to study the spectra of molecules containing carbon (for which the 13C isotope is measured), or to image the distribution of phosphorus in tissues (for which the 31P isotope is measured). Because they are intended to cover a wide range of research applications, preclinical MRI/MRS scanners often have the ability to measure many different isotopes. In contrast, clinical MRI/MRS scanners are nearly universally designed to measure only proton signals, and are unable to measure signals of other isotopes, even when those clinical scanners are employed in research. In some cases, the manufacturers of clinical scanners may offer accessories to measure a limited number of non-proton isotopes, the flexibility of the scanners is limited, their use is cumbersome, and the accessories are usually very expensive. The accessories might be able to function with only a very limited subset of all clinical scanners and cannot be added to most clinical scanners.

It is usually a limitation of a particular scanner's frequency capability that prevents it from exciting or receiving the signals of an isotope. For example, a clinical scanner's electronic components (which experts commonly denote collectively as the scanner console) may be designed to operate only at the proton frequency relevant to its magnet field strength.

Thus, there is a need for systems and methods that empower users of imaging and spectroscopy systems to acquire multinuclear imaging data and/or spectroscopy data without needing to abandon current systems that were not designed to be multinuclear.

### SUMMARY

The present disclosure provides systems and methods that overcome the aforementioned drawbacks by providing systems and methods for adapting MRI or MRS systems that were not designed to be multinuclear to be configurable to acquire data from a variety of X-nuclear spins. For example, one or more conversion units may be utilized to configure an MRI or MRS system to operate at a selected frequency that differs from the proton Larmor frequency at the scanner's magnetic field strength.

In one aspect of the present disclosure, a method of acquiring MR signals from any of a plurality of target isotopes using a proton-only MR system is disclosed. The method comprises connecting a frequency conversion system configured to provide multinuclear imaging to the MR system. The frequency conversion system performs the steps of sampling radio frequency (RF) transmitter pulses generated by the MR system at a first frequency and converting the sampled pulses at the first frequency to a second frequency corresponding to a Larmor frequency of a target isotope to create converted pulses. The system further performs the steps of amplifying the converted pulses to create amplified pulses, routing the amplified pulses to a transmit/receive switch connected to an RF coil for exciting target isotopes present in a volume, and receiving MR signals indicative of nuclear spins of the target isotopes. The method further includes amplifying the MR signals, converting the MR signals to the first frequency to create converted MR signals, and routing the converted MR signals to a receiver of the MR system.

In another aspect, a frequency conversion system for acquiring MR signals from any of a plurality of target isotopes using an MR system configured for protons is disclosed. The system comprises a first conversion unit configured to be connected to receive sampled pulses generated by the MR system at a first frequency and to convert the sampled pulses at the first frequency to a second frequency corresponding to a Larmor frequency of a target isotope to create converted pulses and deliver the converted pulses to carry out a pulse sequence by the MR system on a subject. The system further comprises a second conversion unit configured to receive MR signals from the subject and to convert the MR signals from the second frequency to the first frequency and deliver the converted MR signals to the MR system.

In one aspect of the present disclosure, a method of circumventing a multinuclear accessory of an MR system is disclosed. The method comprises connecting a frequency conversion system configured to provide multinuclear imaging to the MR system. The frequency conversion system performs the steps of sampling radio frequency (RF) transmitter pulses generated by the MR system at a first frequency and converting the sampled pulses at the first frequency to a second frequency corresponding to a Larmor frequency of a target isotope to create converted pulses. The system further performs the steps of amplifying, using an amplifier, the converted pulses to create amplified pulses, routing the amplified pulses to a transmit/receive switch connected to an RF coil for exciting target isotopes present in a volume, and receiving MR signals indicative of nuclear spins of the target isotopes. The method further includes amplifying, using a pre-amplifier, the MR signals, converting the MR signals to the first frequency to create converted MR signals, and routing the converted MR signals to a receiver of the MR system.

In another aspect, a frequency conversion system for circumventing a multinuclear accessory of an MR system is disclosed. The system comprises a first conversion unit configured to be connected to receive sampled pulses generated by the MR system at a first frequency and to convert the sampled pulses at the first frequency to a second frequency corresponding to a Larmor frequency of a target isotope to create converted pulses and deliver the converted pulses to carry out a pulse sequence by the MR system on a subject. The system further comprises a second conversion unit configured to receive MR signals from the subject and to convert the MR signals from the second frequency to the first frequency and deliver the converted MR signals to the MR system.

In one aspect of the present disclosure, a method of functionalizing an MR system including an MR console designed to work at a first field strength with an MR magnet at different field strength is disclosed. The method comprises connecting a frequency conversion system configured to provide multinuclear imaging to the MR system. The frequency conversion system performs the steps of sampling radio frequency (RF) transmitter pulses generated by the MR system at a first frequency and converting the sampled pulses at the first frequency to a second frequency corresponding to a Larmor frequency of a target isotope in the MR magnet to create converted pulses. The system further performs the steps of amplifying the converted pulses to create amplified pulses, routing the amplified pulses to a transmit/receive switch connected to an RF coil for exciting target isotopes present in a volume, and receiving MR signals indicative of nuclear spins of the target isotopes. The method further includes amplifying the MR signals, converting the MR signals to the first frequency to create converted MR signals, and routing the converted MR signals to a receiver of the MR system.

In another aspect, a frequency conversion system for functionalizing an MR system including an MR console designed to work at a first field strength with an MR magnet at a different field strength is disclosed. The system comprises a first conversion unit configured to be connected to receive sampled pulses generated by the MR system at a first frequency and to convert the sampled pulses at the first frequency to a second frequency corresponding to a Larmor frequency of a target isotope to create converted pulses and deliver the converted pulses to carry out a pulse sequence by the MR system on a subject. The system further comprises a second conversion unit configured to receive MR signals from the subject and to convert the MR signals from the second frequency to the first frequency and deliver the converted MR signals to the MR system.

These aspects are nonlimiting. Other aspects and features of the systems and methods described herein will be provided below.

### BRIEF DESCRIPTION OF THE DRAWINGS

The description, together with the figures, make apparent to a person having ordinary skill in the art how some embodiments of the disclosure may be practiced. The figures are for the purpose of illustrative discussion and no attempt is made to show structural details of an embodiment in more detail than is necessary for a fundamental understanding of the teachings of the disclosure.

FIG. 1A is a schematic of a frequency conversion system for providing multinuclear imaging capability to a proton-only MR system, according to aspects of the present disclosure.

FIG. 1B is a schematic of the first and second conversion units of the frequency conversion system, according to aspects of the present disclosure.

FIG. 2A is an image of the frequency converter system on a portable cart, including a frequency converter, RF power amplifier, and directional decoupler, according to aspects of the present disclosure.

FIG. 2B is an image of the experimental setup of a phantom, RF coil, TR switch, pre-amplifier, bias-T on a patient table prior to moving into the clinical 3T scanner, according to aspects of the present disclosure.

FIG. 3 is a flowchart of a method for multinuclear imaging or spectroscopic acquisition on a proton-only MR system, according to aspects of the present disclosure.

FIG. 4 is a simplified schematic diagram of the frequency converter circuit for ¹⁵N MR on a 3T (more precisely 2.9T, proton Larmor frequency 123.23 MHz) proton-only MR scanner, according to aspects of the present disclosure. A sampled ¹H transmit pulse from the scanner at the proton Larmor frequency is mixed with a local oscillator (LO) frequency from a synthesizer to translate the pulse to the ¹⁵N frequency (12.49 MHz on this particular MR scanner). The sampled and converted ¹⁵N transmit pulse at the ¹⁵N Larmor frequency is amplified by an RF power amplifier and sent to the coil for ¹⁵N excitation. The ¹⁵N MR signal detected by the coil at the ¹⁵N Larmor frequency is amplified by a low noise preamplifier, mixed with the LO frequency to translated it to the ¹H frequency, and routed to the scanner ¹H receiver. For simplicity, other electronic components such as amplifiers, attenuators, filters, bias tees, etc., are not shown.

FIG. 5A is an ¹⁵N MR spectrum of ¹⁵N-imidazole, a chemical compound containing a planar 5-membered ring containing two nitrogen atoms, with both nitrogen atoms being replaced (labeled) with the ¹⁵N isotope of nitrogen to enable ¹⁵N MR imaging and spectroscopy. Because hydrogen can be chemically bound to one or the other nitrogen atom, the two nitrogen atoms are in equivalent tautomeric forms, and thus appear as a single peak in the ¹⁵N MR spectrum. The spectrum was measured on the said 3T MR scanner using an embodiment of the invention.

FIG. 5B is an axial ¹⁵N image (color) of an ¹⁵N-imidazole phantom (test object) superimposed on its T1-weighted proton image (gray scale) measured on the 3T scanner.

FIG. 6A is a ¹³C MR spectrum showing [1-¹³C] pyruvate and its hydrate form (small peak) measured on the 3T scanner.

FIG. 6B is a coronal ¹³C image (color) of a [1-¹³C] pyruvate phantom superimposed on its T1-weighted proton image (gray scale) measured on the 3T scanner.

FIG. 7A is a ¹³C spectrum of hyperpolarized [2-¹³C] pyruvate solution measured on the 3T scanner. Peaks in the spectrum indicate the presence of the [2-¹³C] pyruvate compound, its hydrate form, and a [1-¹³C] pyruvate doublet peak from the natural abundance ¹³C J_{CC} coupled to the hyperpolarized enriched [2-¹³C] pyruvate. This is the first spectrum measured in the series of time steps shown in FIG. 7B.

FIG. 7B shows the signal decay of hyperpolarized [2-¹³C] pyruvate solution in spectra measured in a series of time steps on the 3T scanner. The figure shows a stack plot of the spectra showing the hyperpolarized signal decay over time via T₁ relaxation.

FIG. 8 is an in vivo (in a live animal) ³¹P spectrum of a rat head acquired in 20 min measured on the 3T scanner. ³¹P peaks typically observed in the head appear in the spectrum including the peak of phosphocreatine (PCr), the three peaks of adenosine triphosphate (ATP), and the peaks of phosphodiesters (PDE), inorganic phosphate (Pᵢ), and phosphomonoesters (PME).

The foregoing features of embodiments will be more readily understood by reference to the following detailed description.

### DETAILED DESCRIPTION

The vast majority of MR scanners are designed to scan protons (that is, the common isotope ¹H of the element hydrogen), since nearly all clinical scans detect the water content of tissues, and water contains hydrogen atoms. However, essentially every element in the periodic table includes at least one isotope which is MR active. Because proton MR is so overwhelmingly practiced, the term “multinuclear” generally is used to refer to MR of elements or isotopes other than ¹H. Some of these elements have great biomedical or medical relevance. Examples of such relevant elements include sodium, carbon, nitrogen, oxygen, and phosphorus, which occur naturally in the body and can report on various biological functions or medical conditions. Other important elements may be used as tracers, including deuterium, helium, fluorine, and xenon. Implanted devices, for example those containing silicone polymers, may contain elements such as silicon that are amenable to MR. The corresponding isotopes of these elements are respectively ²³Na, ¹³C, ¹⁴N, ¹⁵N, ¹⁷O, ³¹P, ²H, ³He, ¹⁹F, ¹²⁹Xe and ²⁹Si. This list is by no means exhaustive. On any given scanner, each isotope has a frequency of operation (its Larmor frequency). If the scanner has been designed to operate at only one frequency (by default the ¹H frequency), then it is not possible to scan an isotope at a different frequency. Therefore, most MR scanners can scan only ¹H.

Some MR scanners can be equipped with proprietary accessories purchased from the manufacturers that enable the scanner to scan a particular non-¹H isotope or a very small plurality (typically 2 or 3) of isotopes. These accessories tend to be extremely expensive and also limited in capability and flexibility. They require proprietary or custom pulse sequences (software modules that direct the scanner's operation) to scan those particular isotopes. The choice of isotopes or frequencies is typically very limited, and some manufacturers charge separately for each isotope.

Experts in this field commonly denote the group of non-proton isotopes collectively as X-nuclei. The practice of MRI and/or MRI measurement of non-proton isotopes is often denoted as multinuclear MRI and/or MRS. MRI and MRS may collectively be referred to as MR. Scanners that are capable of measuring X-nuclei are often called multinuclear scanners. Experts in the field sometime refer to various isotopes including protons as spins. Protons may be denoted by their isotopic representation ¹H. For a given scanner magnetic field strength, each isotope resonates at a particular radiofrequency (RF frequency), requiring the scanner components to have operational capability at the frequency of that isotope. The frequency of the isotope at a particular magnetic field strength may be referred to as the isotope's Larmor frequency. MR scanning may be conducted on a variety of entities such as a chemical or biological sample, a biological specimen, a substance, a material, a biological tissue, an organism, a plant or an animal, a body part, or a human; these entities collectively may be referred to as a subject of an MR scan.

Disclosed herein is an electronic device that equips an MR scanner to perform multinuclear MR imaging and spectroscopy when the scanner does not have multinuclear capability.

Embodiments of the disclosure include an accessory to a proton-only MR scanner that enables it to perform MR of effectively all isotopes of biomedical or medical interest. It is connected to the scanner at only a small number of points of contact that are typically accessible to most users of the scanner, rather than being embedded deep within the physical structure and design architecture of the scanner. Importantly, the device of this invention is portable in the sense that it can readily be connected to the scanner when needed, and disconnected otherwise, and possibly shared among multiple scanners of the same vendor, as well as scanners made by different vendors. Its operating frequency is variable to cover most all biologically relevant isotopes at a range of magnetic field strengths.

In one embodiment, the system operates by sampling the RF transmitter pulses generated by the scanner at its ¹H operating frequency, shifting the pulse frequency to that of the desired isotope (a process known as frequency conversion or down conversion), applying the frequency—shifted pulses to an RF power amplifier (which substitutes for the scanner's built-in ¹H RF power amplifier), routing the amplified pulses to a transmit/receive switch and then to an RF coil where the nuclear spins are excited. The received MR signal from the nuclear spins is amplified in a preamplifier, frequency shifted back to the scanner ¹H frequency (up converted) and routed to the scanner's receiver.

Thus, the scanner “thinks” it is conducting a ¹H scan, but in fact it is conducting a scan of the desired isotope. Therefore, almost all existing ¹H pulse sequences can be used to conduct multinuclear scans. No additional or proprietary or custom software on the scanner is required. Scanning a different isotope is accomplished by changing one or a small number of settings in the frequency converter, plus changing the preamplifier, RF coil and possibly transmit/receive switch, all of which are easily changed external accessories similar to the manner in which a scanner operator changes from one RF coil to another depending on the body part being scanned. The RF power amplifier associated with the frequency converter can be wideband, such that it is capable of working at all the isotope frequencies of interest. The frequency conversion electronic circuitry itself, the RF power amplifier, the pre-amplifier, the transmit/receive switch and the RF coil can all be considered part of the accessory denoted as “frequency converter”. The pulse sampling, frequency conversion, amplification, filtering and other processes may be carried out with analog electronic components or digital electronic components or a combination of both.

There is increasing interest in in-vivo deuterium metabolic imaging, ³¹P spectroscopy of energy metabolism, hyperpolarized ³He or ¹²⁹Xe gas imaging, and hyperpolarized ¹³C or ¹⁵N MR spectroscopy and MR imaging to assess metabolic flux into various metabolic pathways in animal and human research. While small bore high-field (preclinical) MR scanners typically have built-in capabilities for detecting signals from these non-proton nuclei, X-nuclear MR research involving large animals and humans is limited to special clinical MR scanners that are equipped with multinuclear systems (MNSs) provided by the scanner manufacturer. Yet, some of the major-vendor MNSs do not cover the frequencies of isotopes with low magnetogyric ratios, such as ²H and ¹⁵N.

In a non-limiting example, the present invention enables the user of a proton-only MR scanner to conduct multinuclear measurements. In another non-limiting example, the present invention also enables the user of an MR scanner with a multinuclear accessory to circumvent said multinuclear accessory to measure isotopes that cannot be measured with the said multinuclear accessory. In yet another non-limiting example, the present invention also enables the user of an MR system including an MR console designed to work at a first field strength to use a magnet of a different field strength. This last feature may be of great importance to a researcher who, for example, would like to use a clinical scanner console and its highly sophisticated software and other features with a high field small bore magnet much better suited to animal research than is a typical clinical magnet.

Frequency conversion techniques were frequently used in early-day ultra-high field MRI systems. The original implementation of the 7T whole body MRI scanner at the Massachusetts General Hospital utilized frequency conversion to interface a Siemens Sonata 64 MHz MR scanner console (intended by the manufacturer to be used with a 1.5T magnet) to a 7T magnet with a proton Larmor frequency of 298 MHz. Similarly, frequency conversion enabled the interfacing of a Siemens Trio console (nominal operating frequency of 123 MHz for an approximately 3T magnet) to a 619 MHz (14.56 T) Magnex animal magnet in the same research laboratory.

Frequency conversion techniques have also been used for proton high-resolution imaging and X-nuclear MRS/MRI on MR scanners of typical clinical field strengths. For example, proton microscopic imaging and hyperpolarized ³He imaging were performed at 2T at Duke University using a frequency conversion interface with a GE Signa 64 MHz console. The utility of frequency conversion to measure ³¹P MR images of the calcium phosphate mineral in bone was demonstrated for an MR scanner that had a multinuclear accessory. In this case, although the scanner was capable of measuring ³¹P MR images of soft tissue, its multinuclear accessory did not have the very high-speed performance required to measure ³¹P images of solid tissues such as bone. The frequency converter made use of the normal ¹H channel of the MR scanner which did have the required high-speed capability. As a third example, frequency conversion made possible scanning hyperpolarized ³He gas on a 3T proton-only scanner.

A benefit of the frequency converter device described herein includes its portability coupled with its minimal “invasiveness” in the sense that it requires essentially no scanner modifications and is relatively simple and quick to connect to a working scanner. These are advantages especially in a busy clinical environment where workflow, performance and reliability are critical. Furthermore, clinical scanners must be maintained under service contracts, and not maintained by lab researchers and technicians as is often the case in many NMR and preclinical MRI labs. It is therefore important to minimize the risk of violating warranty and service contract terms as well as reducing the possibility of inadvertently leaving the scanner in an inoperative state after removing the device. The device described herein is configured to have minimal points of contact with the scanner hardware. The connections are primarily through the interface that is routinely used to connect RF coils, which are routinely connected and disconnected by users. Moreover, a hospital typically houses MRI scanners made by different vendors and the device described herein is configured to connect with clinical MRI scanners made by the same vendor and by different vendors. This time-sharing concept of utilizing a single portable frequency converter system to acquire multinuclear MR images and spectra on any clinical scanner in the same hospital will yield a significant financial saving.

Existing multinuclear accessories may utilize frequency conversion at internal system levels, not as a portable device. As provided herein, a modern, portable design of the frequency converter system is presented. Furthermore, its utility is demonstrated in 31p, BC and ¹⁵N MRS and MRI on a clinical proton-only MR scanner in the Example section below.

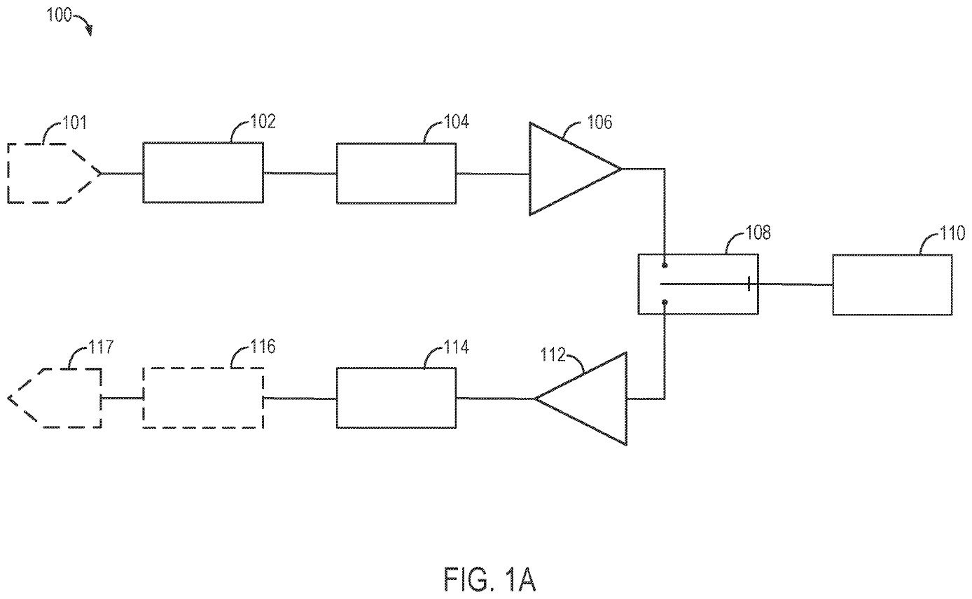

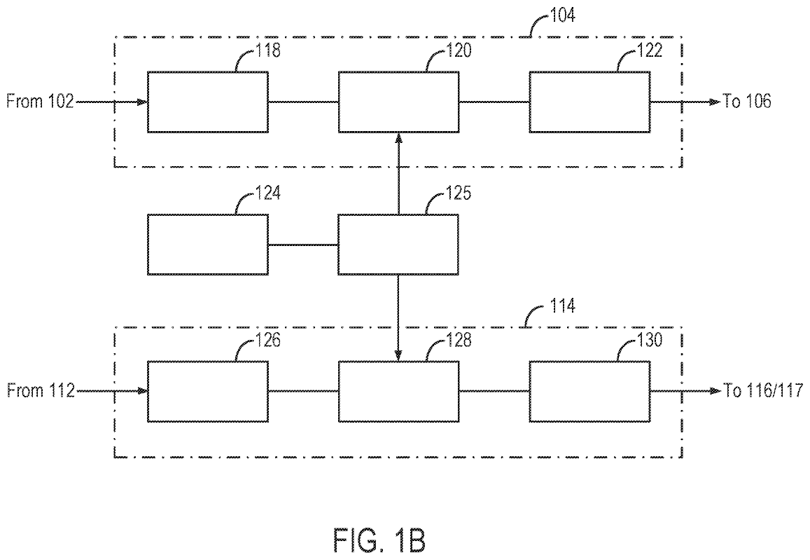

In a non-limiting example, a frequency converter system 100 is illustrated in FIG. 1A. The system 100 is configured to reversibly attach to an MR system 101 without multinuclear capability, such as a ¹H proton MRI system. The system includes a sampling device 102 such as a directional coupler or attenuator configured to sample pulses from a scanner in an MR system 101 at a first frequency. In one non-limiting example using a Siemens 3T ¹H proton MRI system, the nominal Larmor frequency is about 123 MHz because the true magnet field strength is 2.9T. For other MRI systems with different magnet field strength, the nominal Larmor frequency would be different.

In a non-limiting example, the MR system 101 includes an MR console which generates the sampling RF transmitter pulses. Further, the MR console is configured operate a specific field strength. In the non-limiting embodiment for functionalizing the MR system 101 to operate with an MR magnet of a different field strength, the MR console may be designed to work at 3T but functionalized with the frequency conversion system described herein to work with a 15T MR magnet.

The pulses are then converted in a first conversion unit 104 to a second frequency corresponding to a Larmor frequency of a target isotope. In a non-limiting example, the target isotope may be ²³Na, ¹³C ¹⁴N, ¹⁵N, ¹⁷O, ³¹P, ²H, ³He, ¹⁹F, ¹²⁹Xe, ²⁹Si or ⁷Li. Table 1 shows the Larmor frequencies of several isotopes in a “3T” (more precisely 2.9T) MR system.

TABLE 1
Bandpass filter performance for various nuclear isotopes.

| | Frequency @ 3T | Mini-Circuits | IL, | IL, |
|---|---|---|---|---|
| Isotope | (MHz) | bandpass filter | dB @ NF^{a} | dB @ ¹H^{b} |
| ³¹P | 49.89 | BBP-60+ | 3.2 | 33 |
| ¹³C | 30.99 | BBP-30+ | 1.0 | 51 |
| ²H | 18.92 | BBP-20R5+ | 2.3 | 70 |
| ¹⁵N | 12.49 | BBP-10.7+ | 1.2 | 64 |
| ¹H | 123.24 | Note c | >80^{d} | 4.9 |

^{a}Insertion loss of the filter in dB at the nuclear frequency
^{b}Insertion loss of the filter in dB at the proton frequency
^{c}K&L Microwave 6LB10-127.27/T5-B/B (6 MHz 3 dB bandwidth)
^{d}For all nuclear frequencies

Furthermore, system 100 may optionally include an amplifier 106 configured to amplify the sampled pulses at the second frequency. In a non-limiting example, the amplifier 106 is a power amplifier. In a non-limiting example, a transmit/receive (T/R) switch 108 directs the converted sampled pulses at the second frequency to a RF coil 110 configured to transmit the converted sampled pulses to a volume in the scanner of the MR system. The RF coil 110 is also configured to receive MR signals from the volume after transmission of the sampled pulses at the second frequency. Alternatively, the T/R switch 108 may be excluded and a separate RF coil may be used to receive MR signals.

The system 100 may further include a pre-amplifier 112 configured to amplify the MR signals. Furthermore, the system 100 includes a second conversion unit 114 configured to convert the MR signals back to the first frequency, which is transmitted to a receiver of the MR system 117 through the RF coil interface of the MR system 116. In a non-limiting example, the RF coil interface of the MR system 116 is a coaxial cable.

In a non-limiting example, the first conversion unit 104 includes additional components, as illustrated FIG. 1B. The first conversion unit 104 includes a first bandpass filter 118 configured to pass sampled pulses at the first frequency. For example, the bandpass filter selects for ¹H frequency of 123.23 MHz to filter out spurious frequencies from the pulses generated by the scanner of the MR system. Further, the filtered pulse sequence at the first frequency is passed to a first mixer 120 such that the low power sampled pulses at the first frequency are “frequency mixed” with an appropriately chosen local oscillator (LO) frequency. Mixing the sampled pulses at the first frequency with the LO frequency generates output signals with frequencies at the sum and at the difference of the input frequencies. Signals at still other frequencies may appear at the output of the frequency mixer because of device imperfections and extraneous signals from the scanner. The mixed signal may then be passed through a second bandpass filter 122 to select for the second frequency corresponding to the Larmor frequency of the target isotope, while rejecting the undesired frequencies.

In a non-limiting example, second conversion unit 114 includes the identical or similar components of the first conversion unit 104, but in reverse order. In other words, the MR signals passed through the pre-amplifier are filtered by a third bandpass filter 126 selected for the second frequency. Thereafter the filtered MR signals are frequency mixed in a second mixer 128 with the LO frequency and passed through a fourth bandpass filter 130 to select for the first frequency (i.e., operating frequency of the MR system).

In a non-limiting example, the LO 124 generates the LO frequency signal whereafter it passes through a power divider 125 to pass the LO frequency signal to the first mixer 120 and the second mixer 128.

The frequency conversion system and its individual components are described in further detail in the example section below.

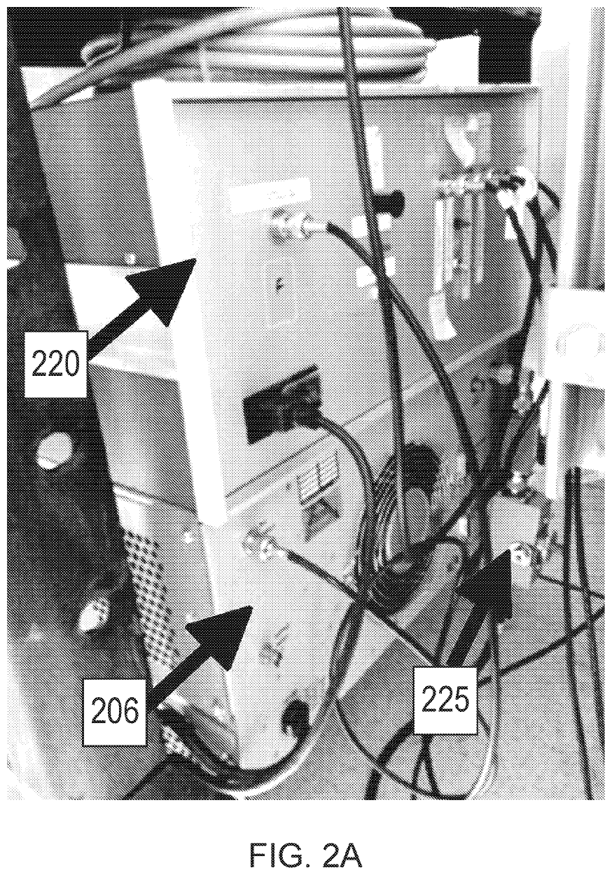

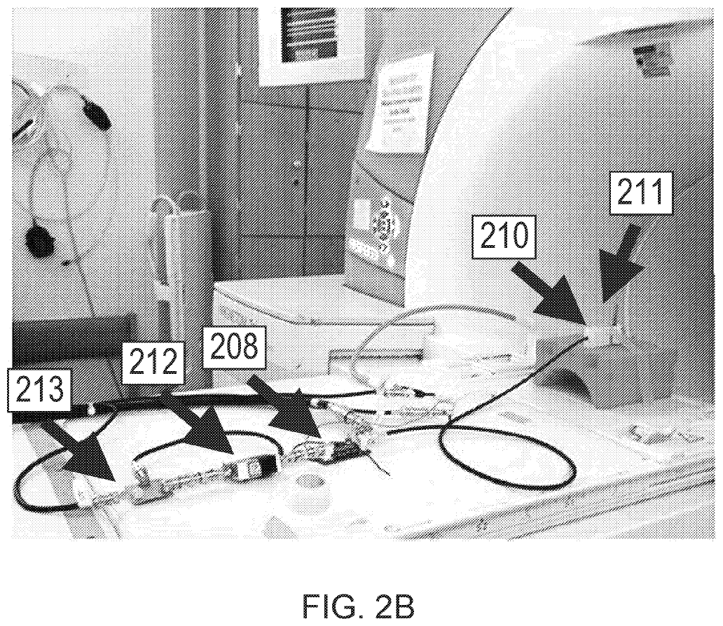

In a non-limiting example, FIGS. 2A-2B show photographs of the frequency conversion system used in a 3T MRI scanner. In a non-limiting example, the mixers, filters and other components of the frequency converter are enclosed in an enclosure 220. The enclosure 220, the power amplifier 206, and the directional decoupler 225 are provided on a portable cart (FIG. 2A). In a non-limiting example, the enclosure 220 houses the first mixer 120 and second mixer 128 of FIG. 1B. FIG. 2B shows a phantom 211, RF coil 210, T/R switch 208, pre-amplifier 212, and a bias-T 213 positioned on the scanning table movable within the bore of the MRI system.

The system of FIGS. 1A-1B and FIGS. 2A-2B are non-limiting and may include additional circuit components. Similarly, the circuit components may be configured in a different arrangement.

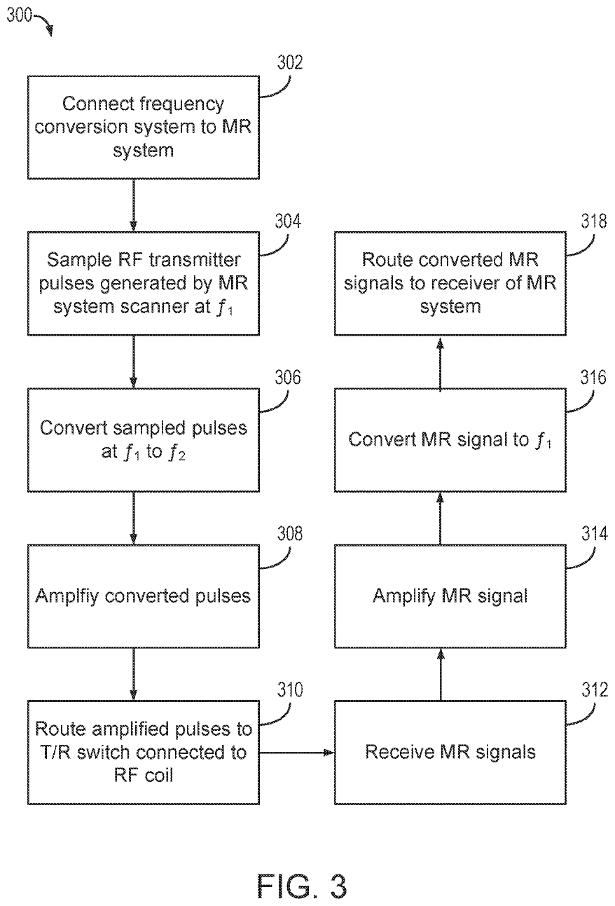

Referring now to FIG. 3, a flow chart describes a non-limiting method 300 of converting the frequency for multinuclear imaging using a single proton MR system. At step 302 a frequency conversion system is connected to an MR system. The frequency conversion system may include any of the embodiments described previously. At step 304, the frequency conversion system is used to sample RF transmitter pulses generated by the scanner of the MR system at a first frequency (f₁). At step 306, the sampled pulses at f₁ are converted to a second frequency (f₂). For example, the first frequency is the ¹H Larmor frequency of a proton-only scanner (~123 MHz) and the second frequency is the Larmor frequency of a target isotope (Table 1).

Converting the sampled pulses at step 306 includes passing the sampled pulses through a first bandpass filter selected for the f₁ to filter out spurious frequencies from the pulses generated by the scanner of the MR system. Further, the filtered pulses are frequency mixed with a LO frequency signal. The mixed pulses are then passed through a second bandpass filter selected for the f₂.

At step 308, the converted pulses are amplified. The pulses may be amplified with a power amplifier. The pulses are then routed to a T/R switch in connection with an RF coil at step 310. Next at step 312, MR signals from the volume are received via the RF coil and amplified at step 314. At step 316, the MR signals is converted to f₁.

Converting the sampled pulses at step 316 includes passing the sampled pulses through a third bandpass filter selected for the f₂. Further, the filtered pulses are frequency mixed with a LO frequency signal. The mixed pulses are then passed through a second bandpass filter selected for the f₁.

At step 318, the converted MR signals are transmitted to a receiver of the MR system. The MR signals can then be processed by the MR system or another system, for image reconstruction or generation of maps or spectrographic maps, or the like.

The steps as described in FIG. 3 are non-limiting and may include additional or omit any filtering, mixing, and amplification steps.

The following example provides a non-limiting example of the development of the system and method implementing that which is described herein.

### EXAMPLE

In light of the growing interest in in-vivo deuterium metabolic imaging, and hyperpolarized ¹³C and ¹⁵N metabolic imaging in large animals on clinical MR scanners, a (radio) frequency converter system is provided to allow X-nuclear MR spectroscopy (MRS) and MR imaging (MRI) on standard clinical MRI scanners without multinuclear capability. This is not only an economical alternative to the multinuclear system (MNS) provided by the scanner vendors, but also overcomes the frequency bandwidth problem of some vendor-provided MNSs that prohibit users from applications with X-nuclei of low magnetogyric ratio, such as deuterium (6.536 MHz/Tesla) and ¹⁵N (−4.316 MHz/Tesla).

The frequency converter system provided herein was used to demonstrate its feasibility for ¹³C (10.708 MHz/Tesla) and ¹⁵N MRS and MRI on a clinical MRI scanner without vendor-provided multinuclear hardware.

In retrofitting mononuclear MR systems with the disclosed system, some scanner parameters, particularly those associated with image dimensions (for example, slice thickness, size of field of view, chemical shift scale) may need to be set differently for multinuclear MR. The analogous parameters in the resultant scan data may similarly need to be relabeled, but this is a simple process that can be accomplished with software external to the scanner if desired.

Disclosed herein is an inexpensive intermediary device (the multichannel receiver and frequency converter) that joins the electronic components of a commercial clinical MRI scanner to a high field animal-size MRI magnet to create a highly cost effective and powerful preclinical tool for advanced biomedical research. Slightly older clinical MRI scanner consoles with their suite of advanced software tools and electronic technology are abundantly and inexpensively available on the used medical device market. A new generation of cryogen-free research grade high field preclinical MRI magnets is likewise available. With the addition of suitable RF power amplifiers, gradient, shim and RF coils, a high performance multinuclear multichannel instrument is created which surpasses the limitations of both clinical and preclinical MR systems. The feasibility was evaluated in a preclinical MR scanner created by integrating a clinical console with a high field magnet: the multichannel frequency converter which enables a fixed low frequency clinical console to operate at any Larmor frequency, and therefore work with any magnet and any nuclear isotope. The frequency converter translates the pulse sequence generated by the clinical console to whatever Larmor frequency is needed while accurately preserving all RF amplitude and phase relationships, and similarly translates the nuclear signals back to the clinical console operating frequency. The clinical scanner “thinks” it is scanning at its originally designed proton frequency, while it is actually exciting and detecting the Larmor frequency of the chosen isotope and magnet.

### Frequency Converter Design

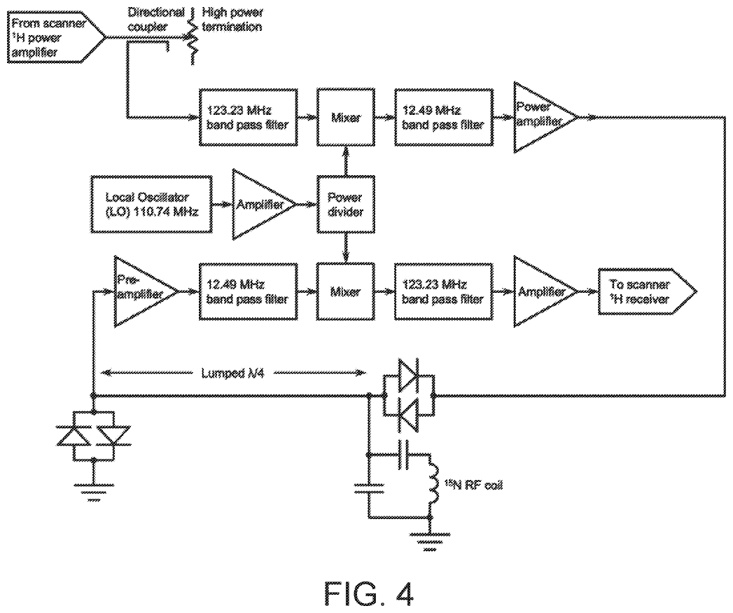

A frequency converter system was assembled to interface with a Siemens Trio 3T MR clinical scanner (Siemens Healthineers, Erlangen, Germany) which was not equipped with multinuclear hardware. In a non-limiting example, FIG. 4 illustrates schematic of the frequency converter setup for ¹⁵N excitation and detection (Larmor frequency of 12.49 MHz at 3T). A low power replica of the ¹H transmit pulse at 123.23 MHz from table plug 1 (for local transmit/receive coils) is sampled with a Bird Electronic (Solon, OH) 553-75 75-150 MHz RF directional coupler element and 4230-059 line section terminating in a Bird 8201 500 watt 50 ohm dummy load capable of handling the full transmit power. The sampled low power ¹H pulse is “frequency mixed” with the appropriately chosen local oscillator (LO) frequency (110.74 MHz) from a Programmed Test Sources (Littleton, MA) PTS-160 frequency synthesizer in a Mini-Circuits (Brooklyn, NY) ZMY-2+ level 23 double balanced mixer. The frequency mixing process amounts to an analog multiplication of the two inputs to the mixer. For two sine wave inputs at frequencies ω₁ and ω₂, the output of the mixer is given by the trigonometric identity:

2 cos ω₁t cos ω₂t=cos(ω₁t+ω₂t)+cos(ω₁t−ω₂t) (1)

Thus, the two sine wave inputs to the mixer result in output sine waves at the sum and difference frequencies. Furthermore, any phase offset or amplitude variations of the input waves are preserved in the output waves. In any physically real mixer, a small amount of each input wave as well as harmonics of the inputs leak through to the output. A Mini-Circuits BBP-10.7+ bandpass filter on the output of the mixer selects the correct 12.49 MHz spectrally pure sideband while rejecting undesired leakage frequencies. This filtered output signal is an exact replica of the proton transmit pulse except now at the ¹⁵N frequency; it carries all of the phase and amplitude variations of the original ¹H pulse.

Although the filter's center frequency is not precisely at the 12.49 MHz Larmor frequency of ¹⁵N, it works extremely well and is an order of magnitude less expensive than purchasing a custom made filter at the exact frequency. Any excess insertion loss at the ¹⁵N frequency is readily made up by the gain of the RF power amplifier (RFPA). Note that the sum frequency sideband (233.97 MHz) as well as the carriers and their harmonics are far out of the filter passband and are therefore fully rejected, leaving a spectrally pure RF pulse. This ¹⁵N RF pulse is then routed to a separate RFPA, an Electronic Navigation Industries (ENI, Rochester, NY) LPI-10 1 kW linear amplifier, rather than the scanner's RFPA, and then to a separate T/R switch and RF coil.

To guard against any spurious frequency content in the scanner's original ¹H RF pulse inadvertently mixing into the filter passband and interfering with ¹⁵N excitation or reception, the ¹H RF pulse replica is passband filtered at 123 MHz before being applied to the mixer.

An analogous arrangement is used on the receive side of the frequency converter: the ¹⁵N signal from the low noise preamp is mixed to the proton frequency in a second double balanced mixer, filtered to select the sideband at the proton frequency, and routed to the scanner receiver. The frequency converter is located next to the scanner electronic cabinets while the ¹⁵N preamplifier is located near the RF coil in the magnet. To power the preamplifier, 12 volts DC is multiplexed onto the same coaxial cable used to route the ¹⁵N RF signal from the preamplifier to the frequency converter with a bias tee. Following the bias tee are two gain stages (Mini-Circuits ZFL-500-BNC, about 24 dB gain each), followed by bandpass filtering (Mini-Circuits BBP-10.7+) and mixing back to the ¹H frequency. The output of the mixer is bandpass filtered (model 6BL10-127.27/T5-B/B, K&L Microwave, Salisbury, MD) and routed to the scanner receiver through table plug 1.

To preserve as much dynamic range as possible in both the excitation pulse and the received signal, “level 23” mixers are used, meaning they are driven by a local oscillator signal at about 23 dBm (about 0.2 watts) or higher. This permits rather high levels of signal on the other input to the mixer to be converted without distortion. To enable this high level mixer drive, the PTS LO output of around 3 dBm is boosted with a Mini-Circuits ZHL-3A amplifier (maximum output 29.5 dBm) and split to each mixer with a Mini-Circuits ZSC-2-1 W+ power divider. Attenuators are used in various locations in the circuit chain to achieve the proper signal levels at each stage.

The low noise preamplifier uses a Mini-Circuits PHA-13LN+ GaAsFET low noise RF amplifier chip biased at 5 VDC and embedded in a passive T/R switch employing crossed diodes and a pi-circuit lumped element quarter wave line; a coaxial line at this very low frequency would be electrically lossy and physically unwieldy. For ¹³C, the same set up was used except different bandpass filters (Mini-Circuits BBP-10.7+), a different LO frequency from the PTS-160 to yield a 31.00 MHz sideband, and a different low-noise preamplifier (Advanced Receiver Research, Burlington CT) were used.

The un-blank logic signal of the ENI RFPA is derived by splitting off the fiber optic un-blank signal of the Siemens console and converting it to Transistor-Transistor Logic.

Table 2 provides a listing of the major electronic components of the frequency converter.

The frequency converter was assembled from a mixture of new components and from parts on hand in the laboratory. This frequency converter had only a single receive channel, but multiple receive channels may be constructed that share certain components with a single transmit channel. Table 2 contains web catalog prices as of April 2023. The most expensive component (an RF power amplifier) are shown with estimated prices. Not included are cabling, connectors, RF coil, preamp, T/R switch and enclosures.

Among the components of the frequency converter, bandpass filters are required before and after the mixers to pass the desired frequency and reject the undesired sideband as well as LO leakage and spurious and intermodulation product frequencies. Bandpass filters at precisely specified frequencies and bandwidths are custom devices and can be expensive. Since their function in the frequency converter is to either pass or reject a small number of specific frequencies, it is in some cases possible to use inexpensive off-the-shelf filters with pass frequencies that are close to but not exactly what is required. Alternatively, bandpass filters can be created with a combination of off-the-shelf lowpass and highpass filters if the correct cutoff frequencies are available. Custom-designed filters can easily be more than ten times the cost of off-the-shelf designs, and custom filter delivery times can be months. Because the filters are not used at critical locations (such as between the preamplifier and the RF coil) insertion losses of several dB are readily tolerated with no degradation in noise figure or overall system performance and can be compensated by adjusting amplifier gains elsewhere in the frequency converter. The filters in this frequency converter are generally tubular filters with coaxial connectors to facilitate quick frequency changes.

The actual magnetic field strength of the Siemens Trio “3T” scanner used in these measurements is 2.89 T (123.24 MHz). In order for readers to assess the choice between using inexpensive stock off-the-shelf bandpass filters and custom designed filters, Table 1 lists the nuclear frequencies of several isotopes that were scanned with the frequency converter along with the insertion loss of Mini-Circuits (Brooklyn, NY, USA) coaxial bandpass filters at the nuclear and proton frequencies. The proton frequency was used as representative of frequencies that must be rejected by these nuclear filters. However, an exact analysis would tabulate all the sideband, carrier and intermodulation product frequencies that could arise, and which must be rejected. The price of a single Mini-Circuits filter in April 2023 was about USD 55 each, whereas the quoted price of a similar custom designed filter at the ¹⁵N frequency was over USD 600 and the delivery time was 14 weeks (K&L Microwave, Salisbury, MD, USA).

TABLE 2
Major electronic components of the frequency converter.
Table 2. Major electronic components of the frequency converter.

| | | | |
|---|---|---|---|
| Component | Source and Model | Quantity | Price each^{a} |

Components for Each Receiver Channel

| | | | |
|---|---|---|---|
| Attenuators | Pasternack Enterprises (Irvine, CA, USA) PE- | 3 | 70 |
| | 7000-3 and PE-7000-10 (3 and 10 dB; used in | | |
| | various locations in the circuit to adjust signal | | |
| | levels; not shown in the FIG. 1) | | |
| Mixers | Mini-Circuits ZAY-1 + double balanced mixer | 2 | 90 |
| | (plug-in version SAY-1 + available) | | |
| Power divider | Mini-Circuits ZSC-2-1W+ | 1 | 63 |
| Amplifier 1 | Mini-Circuits ZHL-3A (between LO and power | 1 | 290 |
| | divider to provide at least 23 dBm to each | | |
| | mixer) | | |
| Amplifier 2 | Mini-Circuits ZFL-500 (two cascaded units | 2 | 101 |
| | separated by 3 dB attenuator following | | |
| | preamp; not shown in FIG. 1; model ZFL-500- | | |
| | BNC + available) | | |
| Bias tee | To optionally provide +12VDC to preamp at | 1 | 105 |
| | magnet via preamp cable (homebuilt; not | | |
| | shown in FIG. 1; Mini-Circuits ZNBT-60-1W + | | |
| | available) | | |
| | | Subtotal | 1,050 |

Shared Components

| | | | |
|---|---|---|---|
| Local oscillator | Programmed Test Sources (Littleton, MA, USA) | 1 | 2,645 |
| | PTS-160 frequency synthesizer (modern | | |
| | synthesizers such as Siglent SSG3021X | | |
| | available; price shown is for the SSG3021X) | | |
| Power amplifier | Electronic Navigation Industries (Rochester, | 1 | 10,000^{b} |
| | NY, USA) LPI-10, no longer available; Tomco | | |
| | Industries (Steprey, Australia) BT00250- | | |
| | AlphaSA available; estimated price shown is for | | |
| | the Tomco. | | |
| Directional coupler | Bird Electronic Corp. (Solon, OH, USA) | | |
| | 553-75 75-150 MHz directional coupler | 1 | 250 |
| | element | | |
| | 4230-018 ⅞″ line section | 1 | 282 |
| | 4240-062 type N female connector | 2 | 23 |
| Termination | Bird 8201 500 W high power load | 1 | 1891 |
| | | Subtotal | 15,114 |
| | | Total | 16,164 |

^{a}Prices in USD as of April 2023:
^{b}estimate

Although none of these filters has a bandpass centered on the target nuclear frequency, their performance in passing the nuclear frequency and rejecting the proton frequency was adequate.

Two filters are required at each nuclear frequency. Note that the specifications of the proton bandpass filters are more stringent, as they must reject frequencies that are fractionally close to the proton frequency (for example the LO frequency and the image frequency). Therefore, a custom designed K&L Microwave 6LB10-127.27/T5-B/B five section bandpass filter was used that was on-hand from previous experiments. The proton filter insertion loss at all the nuclear frequencies is above 80 dB.

### EXPERIMENTAL

The feasibility of the frequency converter system was demonstrated on an ¹⁵N phantom and a ¹³C phantom in two separate experiments. A pulse-and-acquire FID sequence with a hard excitation pulse was used to acquire MRS data. A gradient echo (GRE) sequence was used with altered fields of view and slice thicknesses, as entered in the graphical user interface to the scanner, to account for the magnetogyric ratio between the X-nucleus and proton. In all cases, standard proton sequences were used; the scanner does not “know” it was in fact exciting and acquiring multinuclear signals. For this reason, pulse sequence parameters relating to the magnetogyric ratio (such as scanner frequency, distances and chemical shift scales) are incorrectly excited or labeled because the scanner software does not take the substitution of magnetogyric ratio into account. The user must make the adjustment by specifying altered values for distances to achieve the desired values. However, these parameters are adjustable almost always on the console computer and thus, do not require modifications of pulse sequences.

Thermal ¹⁵N and ¹³C Phantom Experiments

The ¹⁵N phantom was made of 2.4 mL 7 M ¹⁵N-labeled imidazole in a plastic tube of 1.1 cm in diameter and 2.5 cm in length. The ¹³C phantom was made of 1.8 mL 9.3 M [1-¹³C] pyruvate with 10 mM trityl (OX63, Oxford Instrument, UK) in an Eppendorf tube. Both phantoms were doped with a small amount of Gadolinium (Magnevist, Bayer Healthcare, Germany) to shorten T₁ relaxation times. A product gradient echo (GRE) sequence provided by the scanner vendor for proton imaging was used to prescribe a scan of the ¹⁵N phantom with the following scanning parameters: TR/TE/FA=2000 ms/5.69 ms/90°, FOV=320 mm×320 mm (corresponding to an actual FOV of 32.4 mm×32.4 mm for ¹⁵N), matrix size=64×64, spatial resolution=5 mm×5 mm (corresponding to 0.5 mm×0.5 mm for ¹⁵N), a single 250 mm axial slice (corresponding to a 250*4.316/42.5775=25.3 mm slice for ¹⁵N) covering the whole ¹⁵N phantom, receiver bandwidth=90 Hz/pixel, 4 averages, and a total scan time of 8 minutes and 32 seconds. GRE data of the ¹³C phantom was collected using the following scanning parameters: TR/TE/FA=100 ms/5.14 ms/90°, FOV=200 mm×200 mm (corresponding to an actual FOV of 50.3 mm×50.3 mm for ¹³C), matrix size=64×64, spatial resolution=3.1 mm×3.1 mm (corresponding to 0.8 mm×0.8 mm for ¹³C), a single 160 mm coronal slice (corresponding to a 160*10.708/42.5775=40.2 mm slice for ¹³C), receiver bandwidth=260 Hz/pixel, 32 averages, and a total scan time of 3 minutes and 25 seconds. Flip angle calibration was performed on the scanner using the standard manual pre-scan procedure. For the purpose of image display, T1-weighted proton images were acquired on these phantoms by carefully replicating the phantom positions inside a custom-made proton saddle coil.

### Hyperpolarized ¹³C Phantom Experiment

A [2-¹³C] pyruvate sample consisting of 18 μL of >99.0% ¹³C-enriched neat [2-¹³C] pyruvic acid (MilliporeSigma, Massachusetts, USA) and 30 mM trityl AH111501 (Polarize, ApS, Denmark) was hyperpolarized in a 6.7 T d-DNP polarizer (SpinAligner, Polarize, Denmark) for one hour. A 3 mL syringe filled with 2 mL 70% isopropyl alcohol (MilliporeSigma, Massachusetts, USA) was used for localization and frequency calibration. A custom-made ¹³C solenoid coil described above was used for this experiment. After one hour of polarization buildup, hyperpolarized [2-¹³C] pyruvate sample was dissolved rapidly in 3.2 mL dissolution medium, which was prepared in a 1 liter stock consisting of 100 mg of disodium EDTA dihydrate, 5.96 g of Trizma PreSet Crystals pH 7.6 (Sigma-Aldrich T7943), 2.92 g of sodium chloride (NaCl), and 3.20 g of sodium hydroxide (NaOH) in 1 L of distilled H₂O. After dissolution, 2 mL of dissolved hyperpolarized [2-¹³C] pyruvate solution was collected in a 3 mL syringe, de-gassed, rapidly delivered to the 3T clinical scanner, and placed vertically inside the ¹³C solenoid coil at the isocenter. Time from dissolution to the start of acquisition was approximately 30 s. The degree of polarization at the start of acquisition was approximately 40%. Dynamic spectroscopy was acquired with a pulse-and-acquire FID sequence repeated every 3 s (TR) for 3 min with a 10° flip angle, 20,000 Hz spectral bandwidth, and 4096 spectral points. Data reconstruction was performed offline by using custom-made scripts in MATLAB (The Math Works Inc., Massachusetts, USA). The complex raw data were line-broadened by 10 Hz with no zero fill.

### In Vivo ³¹P Experiment

³¹P MRS was performed in an anesthetized Sprague-Dawley rat (Charles River Laboratories International, Inc., Massachusetts, USA) by using an inductively coupled single-loop ³¹P coil of 2 cm in diameter placed on the top of the rat head. Power calibration of the ³¹P coil was performed, prior to the animal experiment, on a 50 mL 2 M monophosphate phantom dopped with 500 μL of gadolinium to shorten the ³¹P T₁ relaxation time. The animal was positioned in an MRI-compatible stereotaxic cradle, with a nose cone connected to an isoflurane vaporizer (2% isoflurane in 30% enriched air). The animal's respiration rate was maintained at approximately 35-40 breaths per minute and monitored visually throughout the experiment. A ³¹P spectrum was acquired from the rat head with the pulse-and-acquire FID sequence with TR of 3 s, 90° flip angle, 8000 Hz spectral bandwidth, 4096 spectral points, and 400 averages for a duration of 20 min. Data reconstruction was performed offline by using custom-made scripts in MATLAB. The complex raw data were line-broadened by 50 Hz, no zero fill, phased with 0th and 1st order phases, and baseline corrected. After the experiment, the animal was fully recovered before being transferred back to the animal facility. The animal experiment was performed in accordance with a protocol approved by the Institutional Animal Care and Use Committee of Massachusetts General Hospital.

### Results

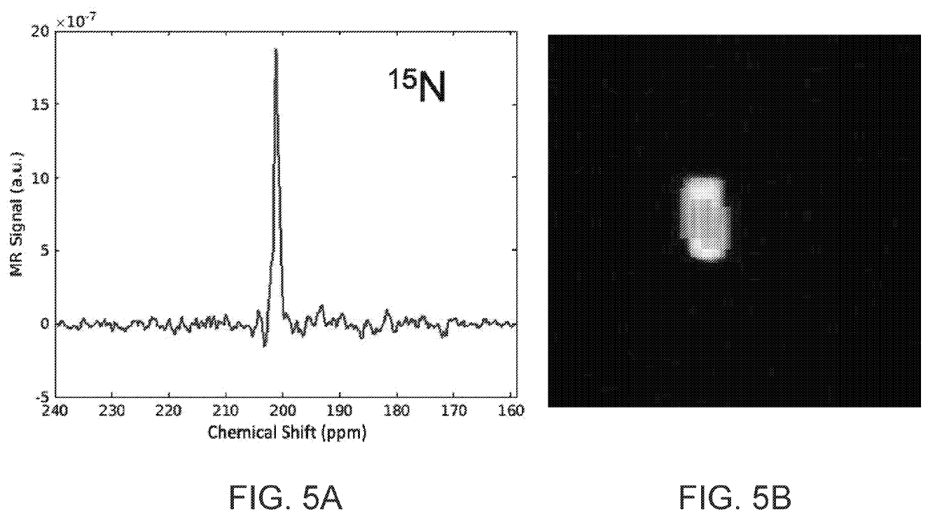

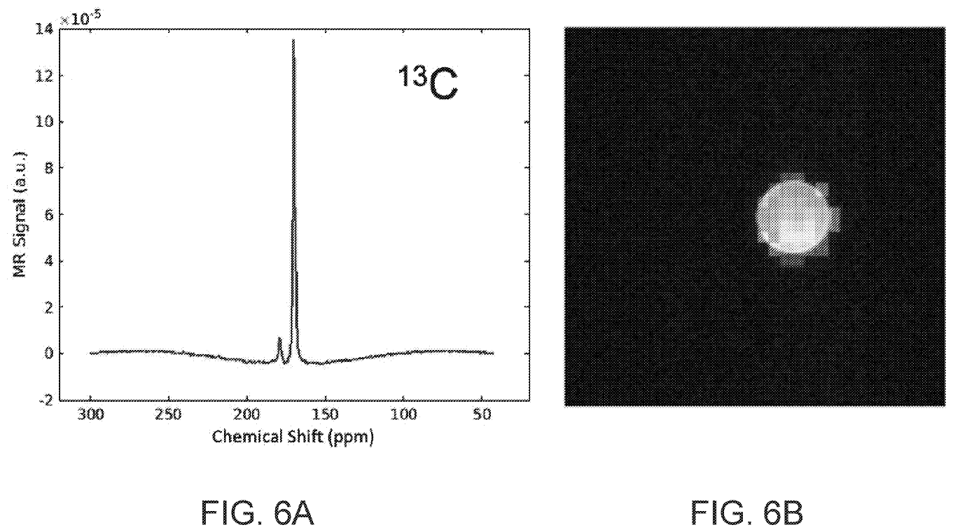

The ¹⁵N image and spectrum of the ¹⁵N-imidazole phantom acquired by using the frequency converter are shown in FIG. 5A-5B, in which the ¹⁵N image (in color) is superimposed on the T1-weighted proton image (in gray scale). The imidazole molecule is a planar 5-membered ring containing two nitrogen atoms; both were labeled with ¹⁵N. Because hydrogen can bind to either nitrogen, the two occur in equivalent tautomeric forms, and thus appear as a single peak in the ¹⁵N MR spectrum. The ¹³C image and spectrum of the [1-¹³C] pyruvate phantom are shown in FIG. 6A-6B. Both the [1-¹³C] pyruvate and its hydrate form appear in the ¹³C spectrum.

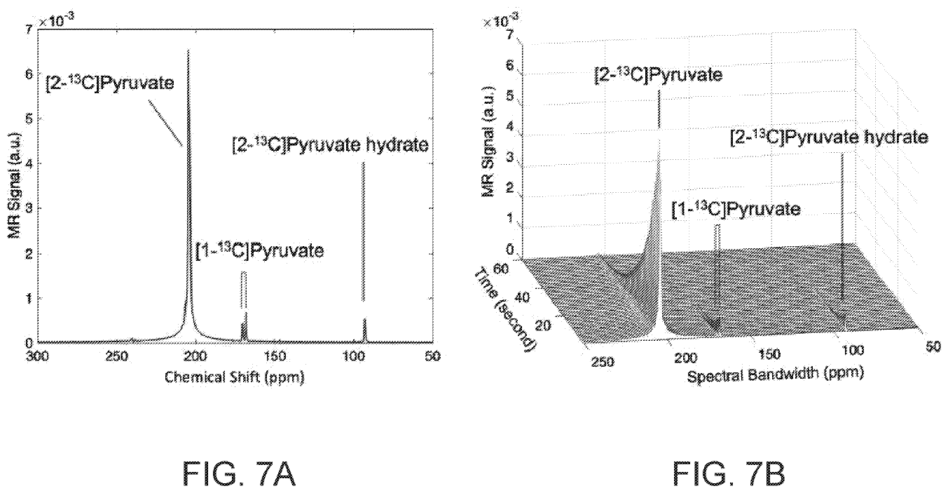

The spectrum of hyperpolarized [2-¹³C] pyruvate solution shows the [2-¹³C] pyruvate peak (206 ppm), [1-¹³C] pyruvate doublet (171 ppm), and [2-¹³C] pyruvate-hydrate (93 ppm), as expected (FIG. 7A). The [1-¹³C] pyruvate doublet is due to J_{CC} coupling between the 1.1% natural abundant ¹³C at the C1 position and the enriched, hyperpolarized ¹³C at the C2 position. ¹³C-pyruvate-hydrate usually appears in the spectrum of ¹³C-pyruvate solution. In the hyperpolarized [2-¹³C] pyruvate experiment, the [1-¹³C] pyruvate-hydrate is simply too small to be detected. Small impurities (148 ppm and 240 ppm) are also observed in the ¹³C spectrum. The stack plot (FIG. 7B) shows exponential delays due to T₁ relaxations and RF depletions. T1 relaxation times are approximately 50 s, 68 s, and 66 s for [2-¹³C] pyruvate, [1-¹³C] pyruvate, and [2-¹³C] pyruvate-hydrate, respectively, after corrections for the flip angles.

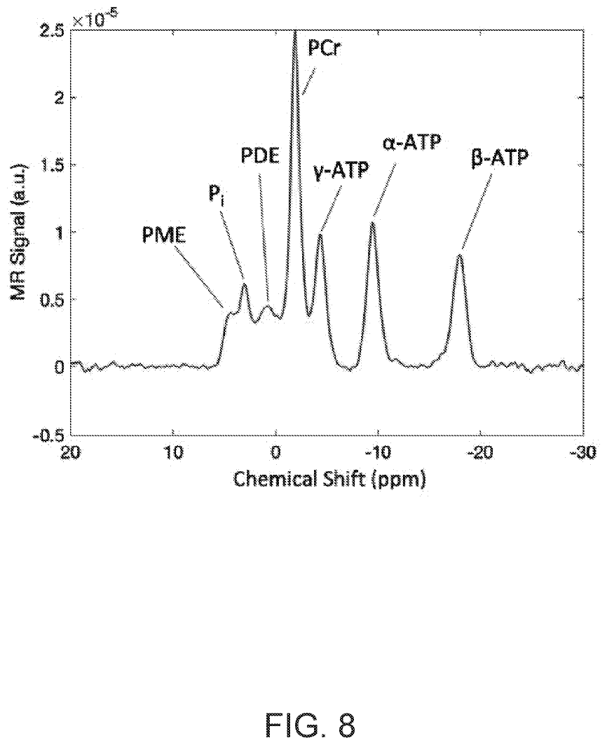

The in vivo ³¹P spectrum of a rat head shows multiple ³¹P peaks (as labeled in FIG. 8) typically observed from brain and muscle (in the head surrounding the brain). Phosphocreatine (PCr) and the three adenosine triphosphate (ATP) peaks are well separated. The phosphodiesters (PDE), inorganic phosphate (Pi), and phosphomonoesters (PME) peaks are somewhat overlapping but likely quantifiable by peak fitting. The quality of the ³¹P spectrum from a 20-min acquisition of a live rat on the standard clinical MR scanner is highly encouraging.

### DISCUSSION

MRS and MRI of ¹³C and ¹⁵N thermal phantoms, hyperpolarized ¹³C dynamic spectroscopy, and in vivo ³¹P MRS on a clinical proton-only 3T scanner has been demonstrated by using a custom-made frequency converter system. This offers possibilities for multiple attractive applications, including deuterium metabolic imaging, hyperpolarized ¹³C or UN MR spectroscopic imaging, and ³¹P MRS to study metabolism in small and large animals, on standard clinical 3T scanners.

Other than adding multinuclear imaging and spectroscopy capability to proton-only scanners, there are additional advantages offered by the frequency converter. In the case of reference Wu et al. (“Bone mineral imaged in vivo by ³¹P solid state MRI of human wrists”, J. Magn. Reson. Imaging, 34 (3) (2011), pp. 623-633, 10.1002/jmri.22637), which involved ³¹P ZTE imaging of very short T2 solid-state signals from bone mineral, the multinuclear accessory on that scanner had a minimum receiver recovery time (the time from the end of an RF pulse to when the MR signal is valid) that was far too long to capture the rapidly decaying MR signal. In contrast, the proton channel of the scanner exhibited a receiver recovery time on the order of 5 μs, more than adequate to carry out solid-state ZTE acquisitions. The frequency converter permitted these acquisitions via the proton channel. In the case of Burns et al. (“Injectable aorta tissue paste for vocal fold medialization: residence time, biocompatibility, and comparison to predicates in a guinea pig subdermal model”, Ann. Otol. Rhinol. Laryngol, 125 (11) (2016), pp. 900-911, 10.1177/0003489416660114), Cohen et al. (“Ex vivo mouse brain microscopy at 15T with loop-gap RF coil” Magn. Reson, Imaging, 51 (2018), pp. 1-6, 10.1016/j.mri.2018.04.010), Cortes et al. (“Assessment of alveolar bone marrow fat content using 15 T MRI” Oral. Surg. Oral. Med. Oral. Pathol. Oral. Radiol, 125 (3) (2018), pp. 244-249, 10.1016/j.oooo.2017.11.016), and Lim et al. (“Pre-amplifiers for a 15-Tesla magnetic resonance imager”, IEEE International RF and Microwave Conference (RFM), Penang, Malaysia (2013), pp. 295-299), a frequency converter enabled a 3T Siemens console to be used with a 15T magnet.

There is a vast library of imaging and spectroscopy pulse sequences developed for proton MR, whereas the array of sequences for other isotopes is very limited, and typically requires special coding and substantial effort. The frequency converter permits researchers to utilize the existing library of sequences developed for protons by making adjustments in distance and frequency related parameters to account for the difference in magnetogyric ratios.

The interface between the frequency converter and the scanner is made at the patient table connector for local T/R coils; the only additional scanner signal access required is to the RF un-blank logic signal. The frequency converter fits in a portable cart. Because of the simplicity of connecting the frequency converter to the scanner and the limited number of “points of contact,” the frequency converter may be readily shared among multiple scanners at multiple field strengths. Changing the frequency of operation requires changing a pair of bandpass filters for either the x-nucleus channel of the frequency converter (and also for the proton channel if the B₀ field is changed).

Although the present implementation of the frequency converter utilizes discrete coaxial RF devices, significant miniaturization is possible with printed circuit board devices or with digital mixing. Either analog or digital single sideband mixing may reduce or obviate the need for analog bandpass filters. In principle, the use of single sideband or digital mixing would provide performance improvements such as reduced spurious frequency interference and increased dynamic range. Miniaturization would be an advantage when expanding the frequency converter to multiple receive channels.

The frequency converter offers a viable low-cost option for adding multinuclear capability to a proton-only scanner, and for sharing the device among multiple scanners made by the same or different vendors with a range of field strengths. Although purchasing a multinuclear accessory from the scanner vendor would be the first choice for adding multinuclear capability to a scanner, this is generally quite expensive in comparison with the frequency converter. In addition, the vendor built-in multinuclear hardware on a dedicated clinical scanner is only utilized for a small fraction of time (as compared to proton imaging). In comparison, the frequency converter is portable and can be transferred to any clinical scanner when multinuclear MRS/MRI is needed on that system regardless of the scanner vendors. This time-sharing concept of utilizing a single portable frequency converter system to acquire multinuclear MR images and spectra on any clinical scanner in the same hospital will yield a significant financial saving. Furthermore, the scanner vendor's multinuclear accessory may be limited to a small number of predetermined isotopes, not necessarily the particular isotope of interest to the experimenter and may come with a limited number of pulse sequences that work with it.

The frequency converter must be reconfigured by exchanging the X-nucleus bandpass filters when changing isotopes. A typical workflow could start with proton MRI using the normally configured scanner, and then be followed by connecting the frequency converter to acquire a ³¹P spectrum. Once the frequency converter is connected, it can be reconfigured by swapping filters and the RF coil (and preamps and T/R switches if they are narrowband) to measure yet a third isotope. The time ordering of the isotopes and whether the measurement is of an image or spectrum are immaterial.

The safety issue of specific absorption rate (SAR) that is relevant for human studies has not yet been addressed herein. A pair of frequency converter stages for the forward and reverse RF power at the transmit coil sampled at the X-isotope frequency via directional couplers can be added to convert these waveforms to the proton frequency, and then supplied to the scanner hardware for real-time SAR monitoring or supplied to a separate SAR monitoring device. However, this does not substitute for the SAR modeling performed by the scanner software before the scan starts. SAR is considerably reduced for X-isotopes and therefore of less concern because of their lower frequency.

Nor was a decoupling channel provided for the frequency converter. Proton decoupling is often part of spectroscopic sequences, particularly for ¹³C, to simplify spectra and promote nuclear Overhauser enhancement. A separate proton CW decoupling channel can readily be added to the frequency converter, but programming more complex pulse sequences such as gated or composite pulse decoupling involves additional challenges.

As used in this specification and the claims, the singular forms “a,” “an,” and “the” include plural forms unless the context clearly dictates otherwise.

As used herein, “about”, “approximately,” “substantially,” and “significantly” will be understood by persons of ordinary skill in the art and will vary to some extent on the context in which they are used. If there are uses of the term which are not clear to persons of ordinary skill in the art given the context in which it is used, “about” and “approximately” will mean up to plus or minus 10% of the particular term and “substantially” and “significantly” will mean more than plus or minus 10% of the particular term.

As used herein, the terms “include” and “including” have the same meaning as the terms “comprise” and “comprising.” The terms “comprise” and “comprising” should be interpreted as being “open” transitional terms that permit the inclusion of additional components further to those components recited in the claims. The terms “consist” and “consisting of” should be interpreted as being “closed” transitional terms that do not permit the inclusion of additional components other than the components recited in the claims. The term “consisting essentially of” should be interpreted to be partially closed and allowing the inclusion only of additional components that do not fundamentally alter the nature of the claimed subject matter.

The phrase “such as” should be interpreted as “for example, including.” Moreover, the use of any and all exemplary language, including but not limited to “such as”, is intended merely to better illuminate the invention and does not pose a limitation on the scope of the invention unless otherwise claimed.

Furthermore, in those instances where a convention analogous to “at least one of A, B and C, etc.” is used, in general such a construction is intended in the sense of one having ordinary skill in the art would understand the convention (e.g., “a system having at least one of A, B and C” would include but not be limited to systems that have A alone, B alone, C alone, A and B together, A and C together, B and C together, and/or A, B, and C together.). It will be further understood by those within the art that virtually any disjunctive word and/or phrase presenting two or more alternative terms, whether in the description or figures, should be understood to contemplate the possibilities of including one of the terms, either of the terms, or both terms. For example, the phrase “A or B” will be understood to include the possibilities of “A” or “B” or “A and B.”

All language such as “up to,” “at least,” “greater than,” “less than,” and the like, include the number recited and refer to ranges which can subsequently be broken down into ranges and subranges. A range includes each individual member. Thus, for example, a group having 1-3 members refers to groups having 1, 2, or 3 members. Similarly, a group having 6 members refers to groups having 1, 2, 3, 4, or 6 members, and so forth.

The modal verb “may” refers to the preferred use or selection of one or more options or choices among the several described embodiments or features contained within the same. Where no options or choices are disclosed regarding a particular embodiment or feature contained in the same, the modal verb “may” refers to an affirmative act regarding how to make or use an aspect of a described embodiment or feature contained in the same, or a definitive decision to use a specific skill regarding a described embodiment or feature contained in the same. In this latter context, the modal verb “may” has the same meaning and connotation as the auxiliary verb “can.”

It will be appreciated by those skilled in the art that while the disclosed subject matter is described above in connection with particular embodiments and examples, the invention is not necessarily so limited, and that numerous other embodiments, examples, uses, modifications and departures from the embodiments, examples and uses are intended to be encompassed by the claims attached hereto. Each article cited herein is incorporated by reference in its entirety.

Various features and advantages of the invention are set forth in the following claims.

1. A method of acquiring MR signals from any of a plurality of target isotopes using a proton-only magnetic resonance (MR) system, the method comprising:
connecting a frequency conversion system configured to provide multinuclear imaging to the MR system, wherein the system performs the steps of:
sampling radio frequency (RF) transmitter pulses generated by the MR system at a first frequency;
converting the sampled pulses at the first frequency to a second frequency corresponding to a Larmor frequency of a target isotope to create converted pulses;
amplifying, using an amplifier, the converted pulses to create amplified pulses;
routing the amplified pulses to a transmit/receive switch connected to an RF coil for exciting target isotopes present in a volume;
receiving MR signals indicative of nuclear spins of the target isotopes;
amplifying, using a pre-amplifier, the MR signals;
converting the MR signals to the first frequency to create converted MR signals; and
routing the converted MR signals to a receiver of the MR system.

2. The method of claim 1, wherein the target isotope comprises at least one of ²³Na, ¹³C ¹⁴N, ¹⁵N, ¹⁷O, ³¹P, ²H, ³He, ¹⁹F, ¹²⁹Xe, ²⁹Si or ⁷Li.

3. The method of claim 1, further comprising passing the sampled pulses through a first bandpass filter selected for the first frequency to filter out spurious frequencies from the pulses generated by the MR system.

4. The method of any one of claims 1-3, further comprising mixing, using a first mixer, the sampled pulses at the first frequency with a local oscillator (LO) frequency.

5. The method of claim 4, wherein converting the sampled pulses includes passing the mixed pulses through a second bandpass filter selected for the second frequency.

6. The method of claim 5, further comprising passing the MR signals through a third bandpass filter selected for the second frequency.

7. The method of claim 6, further comprising mixing, using a second mixer, the MR signals with the LO frequency.

8. The method of claim 7, wherein converting the MR signals includes passing the mixed MR signals through a fourth bandpass filter selected for the first frequency.

9. The method of claim 8, wherein the amplifier, pre-amplifier, first mixer, second mixer, first bandpass filter, second bandpass filter, third bandpass filter, and fourth bandpass filter are analog, digital, or a combination of both.

10. A frequency conversion system for acquiring magnetic resonance (MR) signals from any of a plurality of target isotopes using an MR system configured for protons, the system comprising:
a first conversion unit configured to be connected to receive sampled pulses generated by the MR system at a first frequency and to convert the sampled pulses at the first frequency to a second frequency corresponding to a Larmor frequency of a target isotope to create converted pulses and deliver the converted pulses to carry out a pulse sequence by the MR system on a subject; and
a second conversion unit configured to receive MR signals from the subject and to convert the MR signals from the second frequency to the first frequency and deliver the converted MR signals to the MR system.

11. The system of claim 10, wherein the target isotope comprises at least one of ²³Na, ¹³C ¹⁴N, ¹⁵N, ¹⁷O, ³¹P, ²H, ³He, ¹⁹F, ¹²⁹Xe, ²⁹Si or ⁷Li.

12. The system of claim 10, further comprising a first bandpass filter selected for the first frequency to filter out spurious frequencies from the pulses generated by the MR system.

13. The system of any one of claims 10-12, further comprising a first mixer configured to mix the sampled pulses at the first frequency with a local oscillator (LO) frequency.

14. The system of claim 13, further comprising a second bandpass filter selected for the second frequency.

15. The system of claim 14, further comprising a third bandpass filter selected for the second frequency to filter the MR signals.

16. The system of claim 15, further comprising a second mixer configured to mix the MR signals with the LO frequency.

17. The system of claim 16, wherein the first mixer and second mixer are the same and includes a power divider.

18. The system of claim 16, further comprising a fourth bandpass filter selected for the first frequency.

19. The system of claim 18, wherein the first mixer, second mixer, first bandpass filter, second bandpass filter, third bandpass filter, and fourth bandpass filter are analog, digital, or a combination of both.

20. A method of circumventing a multinuclear accessory of a magnetic resonance (MR) system, the method comprising:
connecting a frequency conversion system configured to provide multinuclear imaging to the MR system, wherein the system performs the steps of:
sampling radio frequency (RF) transmitter pulses generated by the MR system at a first frequency;
converting the sampled pulses at the first frequency to a second frequency corresponding to a Larmor frequency of a target isotope to create converted pulses;
amplifying, using an amplifier, the converted pulses to create amplified pulses:
routing the amplified pulses to a transmit/receive switch connected to an RF coil for exciting target isotopes present in a volume;
receiving MR signals indicative of nuclear spins of the target isotopes;
amplifying, using a pre-amplifier, the MR signals;
converting the MR signals to the first frequency to create converted MR signals; and
routing the converted MR signals to a receiver of the MR system.

21. A frequency conversion system for circumventing a multinuclear accessory of a magnetic resonance (MR) system, the system comprising:
a first conversion unit configured to be connected to receive sampled pulses generated by the MR system at a first frequency and to convert the sampled pulses at the first frequency to a second frequency corresponding to a Larmor frequency of a target isotope to create converted pulses and deliver the converted pulses to carry out a pulse sequence by the MR system on a subject; and
a second conversion unit configured to receive MR signals from the subject and to convert the MR signals from the second frequency to the first frequency and deliver the converted MR signals to the MR system.

22. A method of functionalizing a magnetic resonance (MR) system including an MR console designed to work at a first field strength with an MR magnet at a different field strength, the method comprising:
connecting a frequency conversion system configured to provide multinuclear imaging to the MR system, wherein the system performs the steps of:
sampling radio frequency (RF) transmitter pulses generated by the MR system at a first frequency;
converting the sampled pulses at the first frequency to a second frequency corresponding to a Larmor frequency of a target isotope in the MR magnet to create converted pulses;
amplifying, using an amplifier, the converted pulses to create amplified pulses;
routing the amplified pulses to a transmit/receive switch connected to an RF coil for exciting target isotopes present in a volume;
receiving MR signals indicative of nuclear spins of the target isotopes;
amplifying, using a pre-amplifier, the MR signals;
converting the MR signals to the first frequency to create converted MR signals; and
routing the converted MR signals to a receiver of the MR system.

23. A frequency conversion system for functionalizing a magnetic resonance (MR) system including an MR console designed to work at a first field strength with an MR magnet at a different field strength, the system comprising:
a first conversion unit configured to be connected to receive sampled pulses generated by the MR system at a first frequency and to convert the sampled pulses at the first frequency to a second frequency corresponding to a Larmor frequency of a target isotope to create converted pulses and deliver the converted pulses to carry out a pulse sequence by the MR system on a subject; and
a second conversion unit configured to receive MR signals from the subject and to convert the MR signals from the second frequency to the first frequency and deliver the converted MR signals to the MR system.
